(19) United States
(12) Patent Application Publication
(10) Pub. No.: US 2025/0201537 A1
(43) Pub. Date: Jun. 19, 2025

(54) COMPONENT TO BE USED FOR PLASMA PROCESSING DEVICE, METHOD FOR MANUFACTURING COMPONENT TO BE USED FOR PLASMA PROCESSING DEVICE, AND PLASMA PROCESSING DEVICE

(71) Applicant: Tokyo Electron Limited, Tokyo (JP)

(72) Inventors: Taisei SEGUCHI, Miyagi (JP); Koei ITO, Miyagi (JP)

(73) Assignee: Tokyo Electron Limited, Tokyo (JP)

(21) Appl. No.: 19/070,576

(22) Filed: Mar. 5, 2025

Related U.S. Application Data
(63) Continuation of application No. PCT/JP2023/030266, filed on Aug. 23, 2023.

(30) Foreign Application Priority Data
Sep. 5, 2022 (JP) 2022-140678

(51) Int. Cl. H01J 37/32; C23C 16/24; C23C 16/32; C23C 16/34; C23C 16/40

(52) U.S. Cl. CPC H01J 37/32715; C23C 16/24; C23C 16/325; C23C 16/345; C23C 16/402; H01J 2237/2007

(57) ABSTRACT

A component for use in a plasma processing apparatus, the component comprises a conductive substrate, a plurality of conductive projections, and an Si-containing coating layer. The plurality of conductive projections project from a surface of the conductive substrate and are electrically connected to each other via the conductive substrate. The Si-containing coating layer is formed on the surface of the conductive substrate and surfaces of the plurality of conductive projections such that each of the plurality of conductive projections is partially exposed.

### CROSS-REFERENCE TO RELATED APPLICATIONS

This application is a bypass continuation application of International Application No. PCT/JP2023/030266 having an international filing date of Aug. 23, 2023 and designating the United States, the International Application being based upon and claiming the benefit of priority from Japanese Patent Application No. 2022-140678 filed on Sep. 5, 2022, the entire contents of each are incorporated herein by reference.

### TECHNICAL FIELD

The present disclosure relates to a component to be used for a plasma processing apparatus, a method for manufacturing a component to be used for the plasma processing apparatus, and the plasma processing apparatus.

### BACKGROUND

Japanese Laid-open Patent Publication No. 2001-158666 discloses a method for manufacturing a CVD-SiC self-supporting structure by forming a CVD-SiC film on a substrate and then removing the substrate.

### SUMMARY

The present disclosure provides a technology that reduces electrical resistance and suppresses generation of particles in a component to be used for a plasma processing apparatus.

In accordance with an exemplary embodiment of the present disclosure, a component for use in a plasma processing apparatus comprises a conductive substrate, a plurality of conductive projections projecting from a surface of the conductive substrate and electrically connected to each other via the conductive substrate, and an Si-containing coating layer formed on the surface of the conductive substrate and surfaces of the plurality of conductive projections such that each of the plurality of conductive projections is partially exposed.

### BRIEF DESCRIPTION OF THE DRAWINGS

FIG. 1 illustrates an example configuration of a component for use in a plasma processing apparatus.

FIG. 2 shows a flowchart illustrating a first example of a method for manufacturing a component.

FIGS. 3A-3D illustrate a configuration of a component at each process of the first example of a method for manufacturing a component.

FIG. 4 is a flowchart illustrating an example of a process for disposing a coating layer.

FIG. 5 illustrates an example of a component where the tip and both side surfaces of each conductive projection are exposed.

FIG. 6 is a flowchart illustrating a second example of the method for manufacturing a component.

FIGS. 7A-7C illustrate a configuration of a component at each process of the second example of a method for manufacturing a component.

FIG. 8 illustrates an example of a component where a plurality of conductive projections are integrated with a conductive substrate.

FIG. 9 shows a flowchart illustrating a third example of a method for manufacturing a component.

FIGS. 10A-10C illustrate a configuration of a component at each process of the third example of a method for manufacturing a component.

FIG. 11 is a flowchart illustrating an example of a process for disposing a coating layer.

FIG. 12 illustrates an example of a plasma processing apparatus according to one exemplary embodiment.

FIG. 13 is an enlarged cross-sectional view of part of a plasma processing apparatus according to one exemplary embodiment.

FIG. 14A shows a first disposition example of conductive projections or projections of a component on the top plate of a second chamber.

FIG. 14B shows a second disposition example of conductive projections or projections of a component on the top plate of the second chamber.

FIG. 14C shows a third disposition example of conductive projections or projections of a component on the top plate of the second chamber.

FIG. 14D shows a fourth disposition example of conductive projections or projections of a component on the top plate of the second chamber.

FIG. 15A shows a first disposition example of conductive projections or projections of a component in a lower portion of the second chamber.

FIG. 15B shows a second disposition example of conductive projections or projections of a component in a lower portion of the second chamber.

FIG. 15C shows a third disposition example of conductive projections or projections of a component in a lower portion of the second chamber.

FIG. 15D shows a fourth disposition example of conductive projections or projections of a component in a lower portion of the second chamber.

FIG. 16 illustrates an example of component configuration when the component is applied to the second chamber.

FIG. 17 illustrates an example of configuration of a plasma processing apparatus when a component is applied to the second chamber.

FIG. 18 illustrates an example of configuration of a plasma processing apparatus when a component is applied to the second chamber.

### DETAILED DESCRIPTION

In what follows, each embodiment of the present disclosure will be described.

In accordance with an exemplary embodiment, there is provided a component for use in a plasma processing apparatus comprising a conductive substrate, a plurality of conductive projections projecting from a surface of the conductive substrate and electrically connected to each other via the conductive substrate, and an Si-containing coating layer formed on the surface of the conductive substrate and surfaces of the plurality of conductive projections such that each of the plurality of conductive projections is partially exposed.

In accordance with an exemplary embodiment, the conductive substrate is formed of a first material, the plurality of conductive projections are formed of a second material different form the first material, and each of the plurality of conductive projections is extended into an inside of the conductive substrate.

In accordance with an exemplary embodiment, the first material includes carbon, and the second material includes metal.

In accordance with an exemplary embodiment, the second material includes tungsten or molybdenum.

In accordance with an exemplary embodiment, the plurality of conductive projections are integrated with the conductive substrate.

In accordance with an exemplary embodiment, the conductive substrate and the plurality of conductive projections are formed of tungsten or molybdenum.

In accordance with an exemplary embodiment, the Si-containing coating layer is formed of Si, SiC, Si₃N₄, or SiO₂.

In accordance with an exemplary embodiment, at least one of the plurality of conductive projections has an exposed tip and an unexposed side surface.

In accordance with an exemplary embodiment, at least one of the plurality of conductive projections has an exposed tip and an exposed side surface.

In accordance with an exemplary embodiment, there is provided a method for manufacturing a component for use in a plasma processing apparatus, the method comprises providing a conductive substrate formed of a first material, disposing a plurality of conductive projections on a surface of the conductive substrate, wherein the plurality of conductive projections are formed of a second material different from the first material and electrically connected to each other via the conductive substrate, and forming an Si-containing coating layer on the surface of the conductive substrate and surfaces of the plurality of conductive projections by CVD such that each of the plurality of conductive projections is partially exposed.

In accordance with an exemplary embodiment, the first material includes carbon, and the second material includes metal.

In accordance with an exemplary embodiment, the second material includes tungsten or molybdenum.

In accordance with an exemplary embodiment, the Si-containing coating layer is formed of Si, SiC, Si₃N₄, or SiO₂.

In accordance with an exemplary embodiment, there is provided a method for manufacturing a component for use in a plasma processing apparatus, the method comprises providing a conductive substrate formed of a first material, forming an Si-containing coating layer on a surface of the conductive substrate by CVD, and attaching a plurality of conductive projections on the conductive substrate, wherein the plurality of conductive projections are formed of a second material different from the first material and are electrically connected to each other via the conductive substrate, and each of the plurality of conductive projections is partially exposed from the Si-containing coating layer.

In accordance with an exemplary embodiment, the first material includes carbon, and the second material includes metal.

In accordance with an exemplary embodiment, the second material includes tungsten or molybdenum.

In accordance with an exemplary embodiment, the Si-containing coating layer is formed of Si, SiC, Si₃N₄, or SiO₂.

In accordance with an exemplary embodiment, there is provided a method for manufacturing a component for use in a plasma processing apparatus, the method comprises providing a conductive substrate with a plurality of projections, wherein the conductive substrate is formed of tungsten or molybdenum, and forming an Si-containing coating layer on a surface of the conductive substrate by CVD such that each of the plurality of projections is partially exposed.

In accordance with an exemplary embodiment, the Si-containing coating layer is formed of Si, SiC, Si₃N₄, or SiO₂.

In accordance with an exemplary embodiment, there is provided a plasma processing apparatus comprises an outer chamber, a substrate support disposed within the outer chamber, a lower conductive member disposed around the substrate support and connected to an ground potential, an upper conductive member disposed in an upper part of the substrate support and connected to the ground potential, an inner chamber disposed within the outer chamber to define a processing space for processing a substrate on the substrate support, and an RF power source configured to supply an RF signal to the substrate support to generate a plasma within the processing space, wherein the inner chamber includes a conductive chamber substrate, at least one upper conductive projection projecting from an upper surface of the conductive chamber substrate, at least one lower conductive projection projecting from an lower surface of the conductive chamber substrate and electrically connected to the at least one upper conductive projection through the conductive chamber substrate, and an Si-containing coating layer formed on surfaces of the conductive chamber substrate, the at least one upper conductive projection, and the at least one lower conductive projection such that each of the at least one upper conductive projection and the at least one lower conductive projection has an exposed portion, wherein the exposed portion of the at least one upper conductive projection is in contact with the upper conductive member, and the exposed portion of the at least one lower conductive projection is in contact with the lower conductive member.

In what follows, each embodiment of the present disclosure will be described in detail with reference to appended drawings. Also, the same or similar constituting elements in the respective drawings are given the same reference number irrespective of their drawing symbols, and repeated descriptions thereof will be omitted. Unless otherwise specified, positional relationships such as up, down, left, and right are described based on the positional relationships shown in the drawings. The dimensional ratios in the drawings do not represent actual ratios, nor are the actual ratios limited to the ratios illustrated in the drawings.

### <Example of a Component for Use in a Plasma Processing Apparatus>

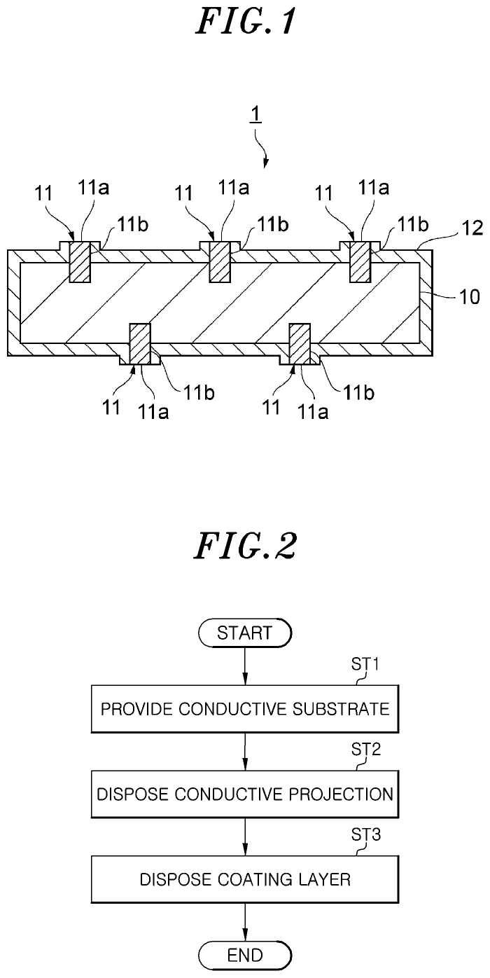

FIG. 1 illustrates an example configuration of a component for use in a plasma processing apparatus. In one embodiment, the component 1 comprises a conductive substrate 10, a plurality of conductive projections 11, and a coating layer 12.

In one embodiment, the conductive substrate 10 is formed of a first material that is a conductor. The first material may be carbon.

In one embodiment, the plurality of conductive projections 11 are disposed on the surface of the conductive substrate 10. The plurality of conductive projections 11 are electrically connected to each other through the conductive substrate 10. A first portion of each conductive projection 11 is disposed within the conductive substrate 10, while a second portion of each conductive projection 11 projects from the conductive substrate 10. In one embodiment, each conductive projection 11 extends into the conductive substrate 10. In one embodiment, the first portion of each conductive projection 11 is embedded within the conductive substrate 10. In one embodiment, the first portion of each conductive projection 11 is disposed in a recess formed in the conductive substrate 10. In one embodiment, the plurality of conductive projections 11 are formed of a second material that is a conductor. In one embodiment, the second material is different from the first material. The second material may be a metal. The second material may be tungsten or molybdenum. The second material may have a lower electrical resistance than the first material. The second material may have greater plasma resistance than the first material. The second material may have higher hardness than the first material.

In one embodiment, the coating layer 12 is disposed (formed) on the surface of the conductive substrate 10 and the surfaces of a plurality of conductive projections 11. In one embodiment, the coating layer 12 is disposed such that the conductive substrate 10 is not exposed, while part of each conductive projection 11 is exposed. In one embodiment, each conductive projection 11 includes an exposed tip 11a that is not covered by the coating layer 12 and an unexposed side surface 11b that is covered by the coating layer 12.

The coating layer 12 includes an Si-containing material. In other words, the coating layer 12 is an Si-containing coating layer. The Si-containing material may include Si, SiC, Si₃N₄, or SiO₂. The coating layer 12 may be formed by Chemical Vapor Deposition (CVD). The coating layer 12 may be a SiC film (CVD-SiC film) formed by CVD. In one embodiment, the coating layer 12 may have higher plasma resistance than the conductive substrate 10. In one embodiment, the conductive substrate 10 or the conductive projections 11 may have lower electrical resistance than the coating layer 12.

### <First Example of a Method for Manufacturing Component 1>

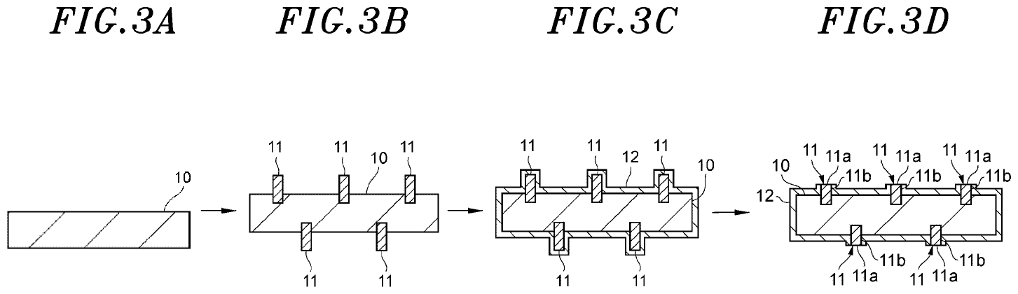

FIG. 2 is a flowchart illustrating a first example of a method for manufacturing component 1. In one embodiment, the method for manufacturing the component 1 includes a process ST1 of providing a conductive substrate 10, a process ST2 of disposing a plurality of conductive projections 11 on the surface of the conductive substrate 10, and a process ST3 of disposing (forming) a coating layer 12 on the surface of the conductive substrate 10 and the surfaces of the plurality of conductive projections 11 such that part of each conductive projection 11 is exposed. FIG. 3 illustrates the configuration of the component 1 in each process of the method for manufacturing the component 1.

In the process ST1 according to one embodiment, a conductive substrate 10 is prepared as shown in FIG. 3A. The conductive substrate 10 may be formed into a predetermined shape that defines the external shape of the component 1.

In the process ST2 according to one embodiment, as shown in FIG. 3B, a plurality of conductive projections 11 are embedded in the surface of the conductive substrate 10. In one embodiment, a plurality of holes or grooves may be formed in the conductive substrate 10, and the conductive projections 11 may be inserted into the holes or grooves. The conductive substrate 10 and the conductive projections 11 may be connected to each other using connection means such as screws or adhesives. The first portion of each conductive projection 11 is disposed within the conductive substrate 10, and the second portion of each conductive projection 11 projects from the conductive substrate 10. The plurality of conductive projections 11 are electrically connected to each other through the conductive substrate 10.

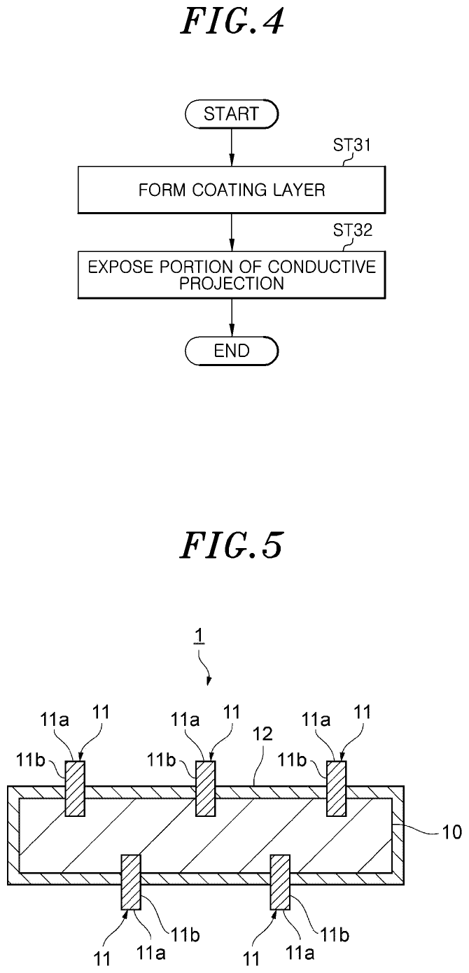

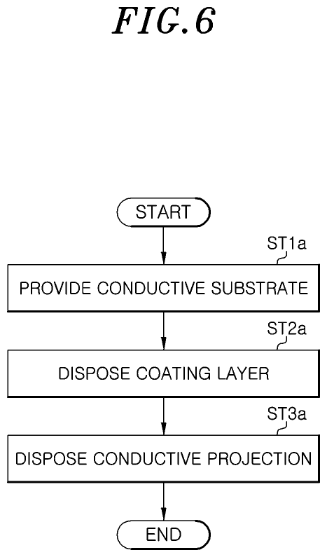

In one embodiment, as shown in FIG. 4, the process ST3 may include a process ST31 of forming a coating layer 12 on the surface of the conductive substrate 10 and the conductive projections 11, and a process ST32 of exposing a portion of each conductive projection 11.

In the process ST31 according to one embodiment, as shown in FIG. 3C, a coating layer 12 is formed over the entire surface of the conductive substrate 10 and the conductive projections 11 by CVD.

In the process ST32 according to one embodiment, as shown in FIG. 3D, a portion of the coating layer 12 is trimmed, and a portion of each conductive projection 11 is exposed. At this time, a portion of each conductive projection 11 may also be trimmed. The coating layer 12 and each conductive projection 11 may be trimmed so that their upper surfaces form the same plane. Each conductive projection 11 may have an exposed tip 11a and an unexposed side surface 11b.

In one embodiment, as shown in FIG. 5, in the process ST32, a portion of the coating layer 12 may be trimmed, exposing the tip 11a and both the side surfaces 11b of each conductive projection 11. At this time, each conductive projection 11 may remain untrimmed. This allows the exposed portion of the conductive projections 11 to have a three-dimensional shape, such as a convex shape. Also, a material that easily exposes the coating layer 12 may be pre-applied to cover the portions of the conductive projections 11 corresponding to the areas where the coating layer 12 is to be removed.

### <Second Example of a Method for Manufacturing Component 1>

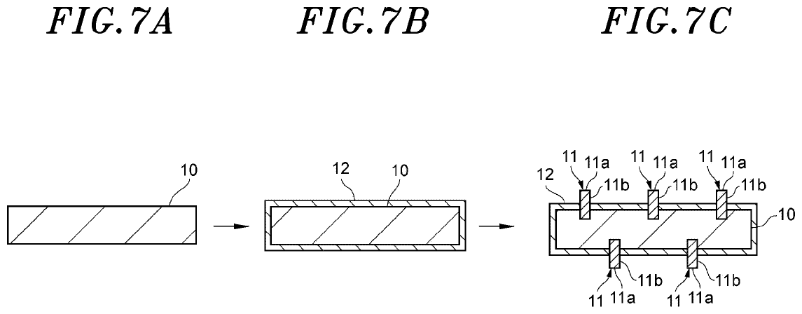

In the method for manufacturing the component 1 described above, the coating layer 12 may be disposed before a plurality of conductive projections 11 are disposed on the surface of the conductive substrate 10. FIG. 6 is a flowchart illustrating a second example of the method for manufacturing the component 1. FIG. 7 illustrates a configuration of component 1 at each process of the second example of the method for manufacturing the component 1. The method for manufacturing the component 1 includes the process ST1a of providing the conductive substrate 10, the process ST2a of disposing (forming) the coating layer 12 on the surface of the conductive substrate 10, and the process ST3a of disposing (attaching) a plurality of conductive projections 11 onto the surface of the conductive substrate 10.

In the process ST1a according to one embodiment, as shown in FIG. 7A, a conductive substrate 10 is prepared.

Next, in the process ST2a according to one embodiment, as shown in FIG. 7B, a coating layer 12 is disposed on the surface of the conductive substrate 10 by CVD.

Next, in the process ST3a according to one embodiment, as shown in FIG. 7C, a plurality of conductive projections 11 are embedded in the surface of the conductive substrate 10. In one embodiment, a plurality of holes or grooves may be formed in the coating layer 12 or conductive substrate 10, and the conductive projections 11 may be inserted into the holes or grooves. The conductive substrate 10 and the conductive projections 11 may be connected to each other using connection means such as screws or adhesives. The first portion of each conductive projection 11 is disposed within the conductive substrate 10, and the second portion of each conductive projection 11 projects from the conductive substrate 10. The plurality of conductive projections 11 are electrically connected to each other through the conductive substrate 10. As a result, the coating layer 12 is disposed on the surface of the conductive substrate 10 and the surfaces of the plurality of conductive projections 11 so that part of each conductive projection 11 is exposed.

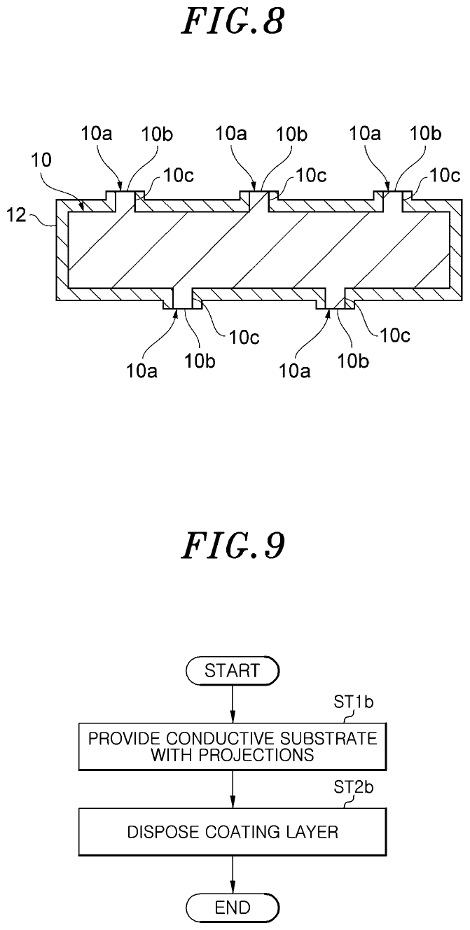

In the component 1, the plurality of conductive projections 11 may be integrated with the conductive substrate 10. FIG. 8 illustrates an example of a component where a plurality of conductive projections are integrated with a conductive substrate. In one embodiment, the component 1 includes a conductive substrate 10 with a plurality of projections (conductive projections) 10a and a coating layer 12. The plurality of projections 10a extend from the main body of the conductive substrate 10. The plurality of projections 10a and the conductive substrate 10 may be formed of tungsten or molybdenum.

### <Third Example of a Manufacturing Method Including a Process 1 of Attaching to a Conductive Substrate>

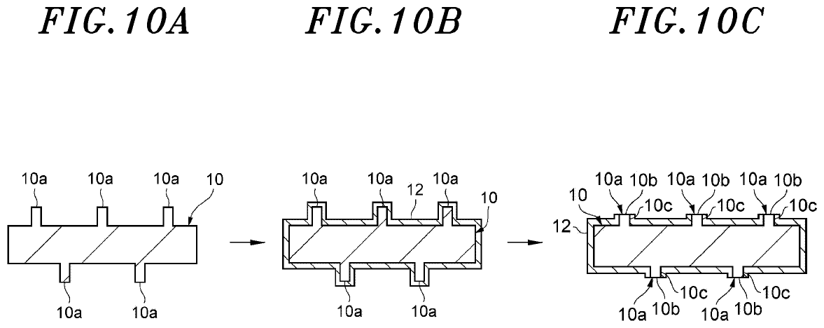

FIG. 9 is a flowchart illustrating a third example of the manufacturing method for the component 1. In one embodiment, the manufacturing method for the component 1 includes a process ST1b of providing a conductive substrate 10 with a plurality of projections 10a, and a process ST2b of disposing (forming) a coating layer 12 on the surface of the conductive substrate 10 using CVD so that part of each projection 10a is exposed. FIG. 10 illustrates the configuration of the component 1 at each process in the third example of the manufacturing method.

In the process ST1b according to one embodiment, as shown in FIG. 10A, a conductive substrate 10 with a plurality of projections 10a is prepared.

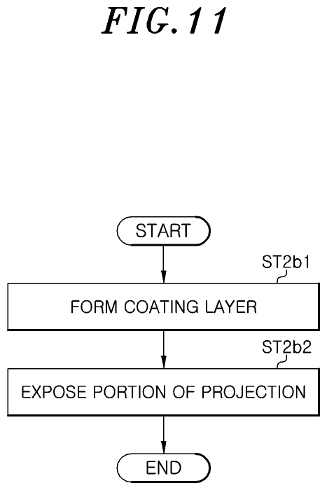

In one embodiment, as shown in FIG. 11, the process ST2b may include a process ST2b1 of forming a coating layer 12 on the surface of the conductive substrate 10 and a process ST2b2 of exposing part of each projection 10a.

In the process ST2b1 according to one embodiment, as shown in FIG. 10B, a coating layer 12 is formed by CVD over the entire surface of the conductive substrate 10 that includes the plurality of projections 10a.

In the process ST2b2 according to one embodiment, as shown in FIG. 10C, a portion of the coating layer 12 is trimmed, and a portion of each projection 10a is exposed. At this time, a portion of each projection 10a may also be trimmed. The coating layer 12 and each projection 10a may be trimmed so that their upper surfaces form the same plane. Each projection 10a may have an exposed tip 10b and an unexposed side surface 10c. Also, the tip 10b and both the side surfaces 10c of each projection 10a may be exposed.

### <One Example of Plasma Processing Apparatus 50>

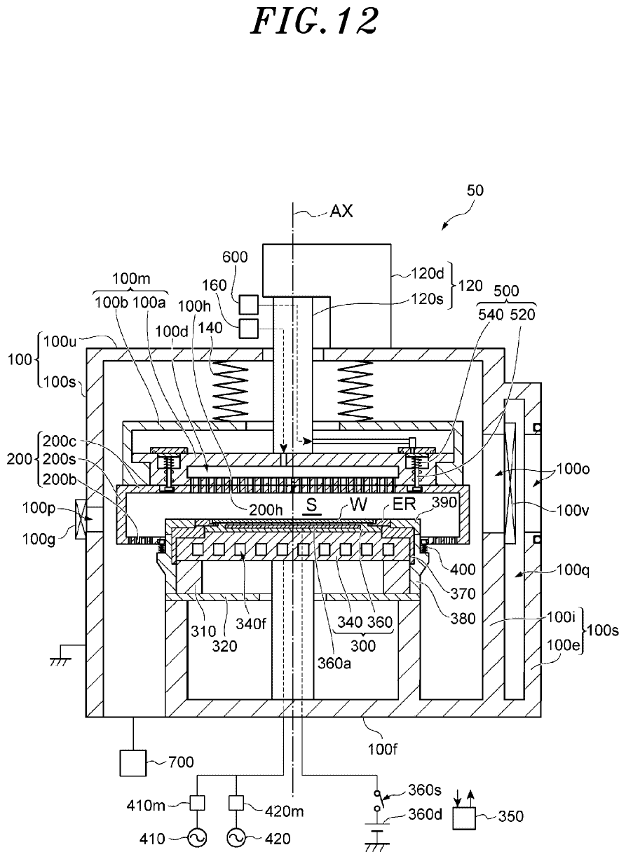

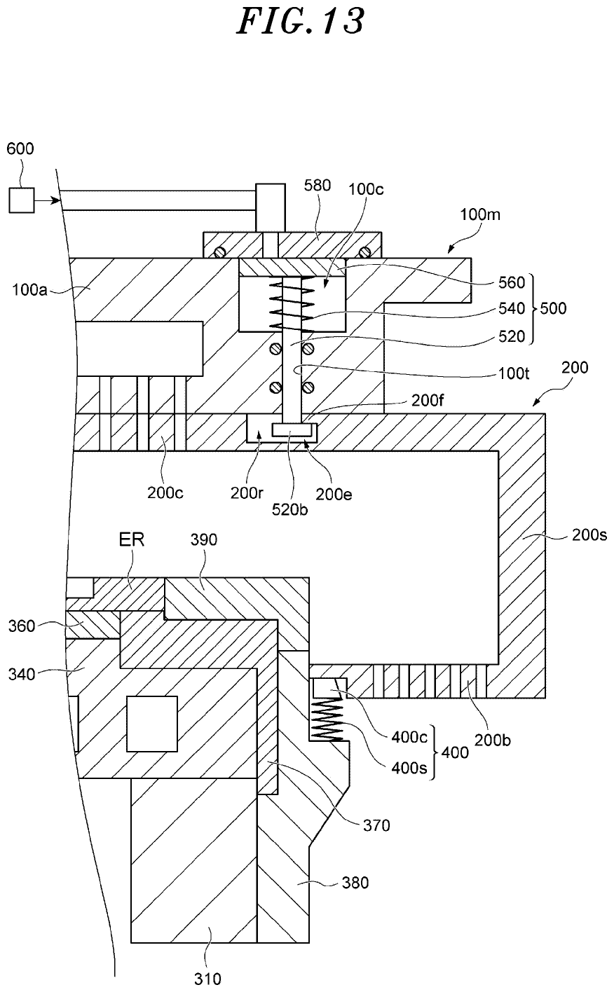

The plasma processing apparatus that employs the component 1 may be a capacitively coupled plasma (CCP) device, an inductively coupled plasma (ICP) device, an electron-cyclotron-resonance (ECR) plasma device, a helicon wave plasma (HWP) device, or a surface wave plasma (SWP) device. FIG. 12 illustrates an example of a plasma processing apparatus 50 in which the component 1 is used according to one exemplary embodiment. FIG. 13 is a partially enlarged cross-sectional view of the plasma processing apparatus 50 according to one exemplary embodiment. In one embodiment, the plasma processing apparatus 50 is a capacitively coupled plasma processing apparatus. As shown in FIG. 12, the plasma processing apparatus 50 includes a first chamber 100, a second chamber 200, and a substrate support 300.

In one embodiment, the first chamber 100 provides an internal space. The first chamber 100 is formed of a conductive metal such as aluminum. The first chamber 100 is electrically grounded. The first chamber 100 is an example of an outer chamber.

In one embodiment, the first chamber 100 includes a sidewall 100s, an upper portion 100u, and a lower portion 100f. The sidewall 100s may have an approximately cylindrical shape. The central axis of the sidewall 100s extends in a vertical direction and is denoted as the axis AX in FIG. 12. A passage 100p is disposed in the sidewall 100s. The internal space of the first chamber 100 may be connected to the internal space of a transfer module installed outside the first chamber 100 via the passage 100p. In one embodiment, the passage 100p may be opened and closed by a gate valve 100g. The substrate W may be transferred between the internal space of the first chamber 100 and the exterior of the first chamber 100 through the passage 100p.

In one embodiment, an opening 100o may be disposed in the sidewall 100s. The opening 100o has a size that allows the second chamber 200 to pass through. In one embodiment, the internal space of the first chamber 100 may be connected to the internal space of the transfer module via the opening 100o. In one embodiment, the opening 100o may be opened and closed by a gate valve 100v. The second chamber 200 may be transferred between the internal space and the exterior of the first chamber 100 through the opening 100o.

In one embodiment, a portion of the sidewall 100s may have a double-layered structure formed by an inner wall 100i and an outer wall 100e. The inner wall 100i and the outer wall 100e provide a space 100q between them. In one embodiment, the opening 100o is formed in both the inner wall 100i and the outer wall 100e. The gate valve 100v may be disposed along the inner wall 100i to open and close the opening 100o.

In one embodiment, the upper portion 100u may have a circular plate shape with its flat surface oriented vertically. The upper portion 100u extends horizontally in a direction perpendicular to the axial line AX from the top of the sidewall 100s. An opening may be disposed in the region where the axial line AX intersects the upper portion 100u.

In one embodiment, the first chamber 100 may further include a movable part 100m. The movable part 100m may or may not constitute a portion of the first chamber 100. In one embodiment, the movable part 100m is provided between the upper portion 100u of the first chamber 100 and the second chamber 200. The movable part 100m may be configured to move up and down within the first chamber 100.

In one embodiment, the plasma processing apparatus 50 may further include a lift mechanism 120. The lift mechanism 120 is configured to move the movable part 100m upward and downward. The lift mechanism 120 may include a drive device 120d and a shaft 120s. The movable part 100m may be fixed to the shaft 120s. The shaft 120s may extend upward from the movable part 100m through the opening in the upper portion 100u. The drive device 120d may be provided outside the first chamber 100. In one embodiment, the drive device 120d is configured to move the shaft 120s upward and downward. The drive device 120d may include, for example, a motor. By the upward and downward movement of the shaft 120s, the movable part 100m may be configured to move upward and downward.

In one embodiment, the plasma processing apparatus 50 may further include a vertically expandable and contractible bellows 140. The bellows 140 may be disposed between the movable part 100m and the upper portion 100u. The lower end of the bellows 140 may be fixed to the movable part 100m. The upper end of the bellows 140 may be fixed to the upper portion 100u. The bellows 140 may separate the internal space of the first chamber 100 located outside the bellows 140 from the external space of the first chamber 100 interacting with the inside of the bellows 140.

In one embodiment, the movable part 100m may include a first member 100a and a second member 100b. The first member 100a and the second member 100b may be fixed to each other. The first member 100a may have an approximately circular plate shape. The first member 100a may be formed of a conductive material such as aluminum. The first member 100a may constitute the upper electrode in the plasma processing apparatus 50. The second member 100b may have an approximately cylindrical shape. The second member 100b may extend along the periphery of the first member 100a. The second member 100b may be positioned above the first member 100a and include a top plate with a surface facing upward. The lower end of the bellows 140 described above may be fixed to the top plate of the second member 100b.

In one embodiment, the movable part 100m may constitute the shower head together with a ceiling portion 200c of the second chamber 200, described later. In other words, the movable part 100m may constitute part of the shower head that supplies gas to the plasma processing space S, described later. In the present embodiment, the movable part 100m may include a gas diffusion chamber 100d and a plurality of gas holes 100h.

In one embodiment, the gas diffusion chamber 100d may be disposed within the first member 100a. A gas supply 160 may be connected to the gas diffusion chamber 100d. The gas supply 160 may be provided outside the first chamber 100. The gas supply 160 may include one or more gas sources, one or more flow controllers, and one or more valves utilized in the plasma processing apparatus 50. Each of the one or more gas sources may be connected to the gas diffusion chamber 100d through a corresponding flow controller and a corresponding valve. The plurality of gas holes 100h may extend downward from the gas diffusion chamber 100d.

In one embodiment, the substrate support 300 is disposed within the first chamber 100 and below the movable part 100m. The substrate support 300 is configured to support the substrate W on its supporting surface. The substrate support 300 may be supported by a support 310 disposed below the substrate support 300. The support 310 may have an approximately cylindrical shape. For example, the support 310 may be formed of an insulating material such as quartz. The support 310 may extend upward from a base plate 320. The base plate 320 may be formed of a conductive metal such as aluminum.

The substrate support 300 may include a lower electrode 340 and an electrostatic chuck 360. The lower electrode 340 may have an approximately circular plate shape. The central axis of the lower electrode 340 may approximately align with the axis AX. The lower electrode 340 may be formed of a conductive material such as aluminum. The lower electrode 340 may have a flow path 340f internally. The flow path 340f may extend, for example, in a spiral shape. The flow path 340f may be connected to a chiller unit 350. The chiller unit 350 may be provided outside the first chamber 100. The chiller unit 350 may supply a coolant to the flow path 340f. The coolant supplied to the flow path 340f may be returned to the chiller unit 350.

The plasma processing apparatus 50 may further include a first radio-frequency (RF) power supply 410 and a second radio-frequency power supply 420. The first radio-frequency power supply 410 is a power source (RF power supply) that generates first radio-frequency power (RF signal). In one embodiment, the first radio-frequency power has a frequency suitable for plasma generation. The frequency of the first radio-frequency power may, for example, be 27 MHz or higher. In one embodiment, the first radio-frequency power supply 410 may be electrically connected to the lower electrode 340 through a matcher 410m. In one embodiment, the matcher 410m may include a matching circuit to match the impedance of the load side (lower electrode 340 side) of the first radio-frequency power supply 410 to the output impedance of the first radio-frequency power supply 410. Also, the first radio-frequency power supply 410 may be connected to the upper electrode instead of the lower electrode 340 through the matching circuit 410m.

The second radio-frequency power supply 420 is a power source (RF power supply) that generates second radio-frequency power (RF signal). In one embodiment, the second radio-frequency power has a frequency suitable for introduction of ions to the substrate W. The frequency of the second radio-frequency power may, for example, be 13.56 MHz or lower. In one embodiment, the second radio-frequency power supply 420 may be electrically connected to the lower electrode 340 through a matcher 420m. In one embodiment, the matcher 420m may include a matching circuit to match the impedance of the load side (lower electrode 340 side) of the second radio-frequency power supply 420 to the output impedance of the second radio-frequency power supply 420.

In one embodiment, the electrostatic chuck 360 is provided on the lower electrode 340. The electrostatic chuck 360 may include a main body and an electrode 360a. The main body of the electrostatic chuck 360 may have an approximately circular plate shape. The central axis of the electrostatic chuck 360 may approximately align with the axis AX. The main body of the electrostatic chuck 360 may be made of ceramic. The substrate W is placed on the upper surface of the main body of the electrostatic chuck 360. The electrode 360a may be formed as a conductive film. The electrode 360a is provided within the main body of the electrostatic chuck 360. The electrode 360a may be connected to a DC power supply 360d via a switch 360s. In one embodiment, when a voltage from the DC power supply 360d is applied to the electrode 360a, electrostatic attractive force is generated between the electrostatic chuck 360 and the substrate W. The substrate W is attracted by the electrostatic attractive force to the electrostatic chuck 360 and held by the electrostatic chuck 360. The plasma processing apparatus 50 may also provide a gas line for supplying a heat transfer gas (e.g., helium gas) into the gap between the electrostatic chuck 360 and the rear surface of the substrate W.

The substrate support 300 may support an edge ring ER disposed on the substrate support 300. The substrate W may be mounted on the electrostatic chuck 360 within the region surrounded by the edge ring ER. The edge ring ER may be made of materials such as silicon, quartz, or silicon carbide.

The plasma processing apparatus 50 may also include an insulator 370. The insulator 370 may be made of an insulating material such as quartz. The insulator 370 may have an approximately cylindrical shape. The insulator 370 may extend along the periphery of the lower electrode 340 and the periphery of the electrostatic chuck 360.

The plasma processing apparatus 50 may further include a conductor 380. The conductor 380 may be formed of a conductive material such as aluminum. The conductor 380 may have an approximately cylindrical shape. The conductor 380 may be provided along the periphery of the substrate support 300. The conductor 380 may extend vertically along the periphery of the insulator 370. The conductor 380 may be connected to the ground. In one example, the conductor 380 may be grounded through the base plate 320 and the lower portion 100f of the first chamber 100.

The plasma processing apparatus 50 may further include a cover ring 390. The cover ring 390 may be made of an insulating material such as quartz. The cover ring 390 may have an annular shape. The cover ring 390 may be provided on the insulator 370 and the conductor 380 so that the cover ring 390 may be positioned outside the region where the edge ring ER is disposed in the radial direction.

The plasma processing apparatus 50 may further include a contact 400. In one embodiment, the contact 400 may be electrically connected to the conductor 380. In one embodiment, while the second chamber 200 forms the plasma processing space S together with the substrate support 300, the contact 400 comes into contact with the second chamber 200. In one embodiment, the contact 400 is disposed outside the cover ring 390 and extends upward from the conductor 380.

The contact 400 may be configured to elastically contact the second chamber 200. As shown in FIG. 13, the contact 400 may include a spring 400s. The contact 400 may further include a contact portion 400c. Both the spring 400s and the contact portion 400c may be conductive. The lower end of the spring 400s may be fixed to the conductor 380. The spring 400s may extend upward from the conductor 380. The contact portion 400c may be fixed to the upper end of the spring 400s. The contact portion 400c may be the part that contacts the second chamber 200.

In one embodiment, as shown in FIG. 12, the second chamber 200 is disposed within the first chamber 100 and configured to form the plasma processing space S together with the substrate support 300. The plasma processing space S may be a space where a plasma is generated and the substrate W is processed. The second chamber 200 may be formed of a conductor. The second chamber 200 is an example of an inner chamber.

In one embodiment, the second chamber 200 may include a ceiling portion 200c, a side portion 200s, and a lower portion 200b. The ceiling portion 200c may have an approximately circular plate shape. The ceiling portion 200c may extend horizontally above the plasma processing space S. The upper surface of the ceiling portion 200c may contact the lower surface of the movable part 100m. The ceiling portion 200c may include a plurality of gas holes 200h. The plurality of gas holes 200h may penetrate the ceiling portion 200c and be open toward the plasma processing space S. Each of the plurality of gas holes 200h may be connected to the plurality of gas holes 100h.

In one embodiment, the side portion 200s may have an approximately cylindrical shape. The side portion 200s may extend primarily along the sides of the plasma processing space S. The side portion 200s may extend downward from the edge of the ceiling portion 200c and may be connected to the edge of the lower portion 200b.

In one embodiment, the lower portion 200b may have an approximately annular shape. The lower portion 200b may extend horizontally from the lower end of the side portion 200s toward the axis AX (center side). The lower portion 200b may contact at least one of the contact 400 and the conductor 380.

A plurality of through-holes may be formed in the lower portion 200b. The plasma processing apparatus 50 may further include an exhaust system 700. The exhaust system 700 may include a pressure regulator, such as an automatic pressure control valve, and a vacuum pump, such as a turbomolecular pump. The exhaust system 700 may be connected to the lower portion 100f of the first chamber 100 from beneath the lower portion 200b.

The second chamber 200 may be detachable from the first chamber 100. In one embodiment, as shown in FIGS. 12 and 13, the plasma processing apparatus 50 may further include a clamp 500 and a release mechanism 600. The clamp 500 may be configured to detachably fix the second chamber 200 to the first chamber 100. The release mechanism 600 may be configured to release the fixation of the second chamber 200 by the clamp 500.

In one embodiment, as shown in FIG. 13, the clamp 500 detachably fastens the ceiling portion 200c of the second chamber 200 to the movable part 100m of the first chamber 100. In one embodiment, the clamp 500 may include a plurality of supports 520, springs 540, and plates 560. Also, the number of supports 520, springs 540, and plates 560 of the clamp 500 may be one or more.

Each of the plurality of supports 520 may have an elongated rod-like shape extending vertically. Each of the plurality of supports 520 may include a lower end 520b protruding horizontally from the main body of the support. The movable part 100m of the first chamber 100 may have a plurality of cavities 100c formed on the top surface of the first member 100a and a plurality of holes 100t extending downward from the cavities 100c and penetrating the first member 100a vertically. The cavities 100c may be sealed by covers 580 provided on the top surface of the first member 100a. The top surface of the ceiling portion 200c of the second chamber 200 may include a recess 200r. Each of the plurality of supports 520 may pass vertically through the cavities 100c and the holes 100t. The lower end 520b of the supports 520 may be positioned within the recess 200r. The recess 200r may include a horizontally extending portion (end) 200e, and an engaging portion 200f may be formed in the recess 200r by the extending portion 200e. The lower end 520b may be secured by the engaging portion 200f.

The plate 560 may be fixed to the upper end of the support 520. The plate 560 may be disposed within the cavity 100c. The spring 540 may be disposed along the support 520 between the lower surface of the cavity 100c and the plate 560. The spring 540 applies upward pressure to the plate 560 relative to the movable part 100m. As a result, the support 520 is pressed upward, which causes the lower end 520b of the support 520 to be pressed into the engaging portion 200f of the ceiling portion 200c, thereby allowing the second chamber 200 to be held and secured to the movable part 100m.

In one embodiment, the release mechanism 600 may include an air supply. The air supply may supply air into the gap between the cover 580 and the plate 560. By supplying air into the gap between the cover 580 and the plate 560, the release mechanism 600 pushes down the plate 560; consequently, the lower end 520b of the support 520 is disengaged from the engaging portion 200f of the ceiling portion 200c, thereby releasing the fixation of the second chamber 200 to the movable part 100m. When the fixation between the second chamber 200 and the movable part 100m is released, the second chamber 200 may be separated from the first chamber 100.

In the plasma processing apparatus 50, the component 1 may be applied to the second chamber 200. The conductive projections 11 or projections 10a of the component 1 may serve as electrical contacts, may be disposed on the upper surface of the ceiling portion 200c of the second chamber 200, and may electrically connect the second chamber 200 to the movable part 100m of the first chamber 100. At this time, the conductive projections 11 or projections 10a may be in contact with the lower surface of the first member 100a. Also, the conductive projections 11 or projections 10a of the component 1 may be disposed on the lower surface or inner circumferential surface of the lower portion 200b as electrical contacts and electrically connect the second chamber 200 to the conductor 380. At this time, the conductive projections 11 or projections 10a may be in contact with at least one of the conductor 380 or the contact 400.

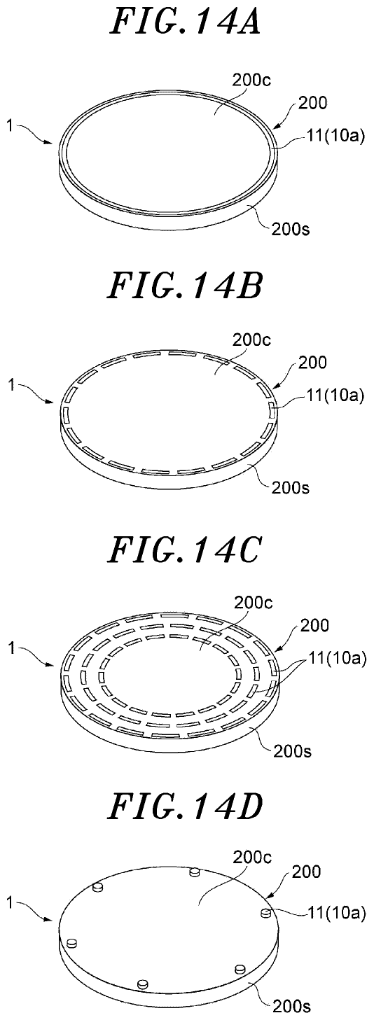

FIG. 14 illustrates examples of disposition of the conductive projections 11 (projections 10a) of the component 1 on the upper surface of the ceiling portion 200c of the second chamber 200. As shown in FIG. 14A, the conductive projections 11 or projections 10a may be disposed in the form of an annular solid-line over the entire circumference of the upper surface of the ceiling portion 200c; as shown in FIG. 14B, the conductive projections 11 or projections 10a may be disposed in an annular dotted-line shape. As shown in FIG. 14C, the conductive projections 11 or projections 10a may also be disposed in the form of a concentric circle on the upper surface of the ceiling portion 200c. At this time, the conductive projections 11 or projections 10a may form a solid-line annular shape or a dotted-line shape over the entire circumference. As shown in FIG. 14D, the conductive projections 11 or projections 10a may be disposed as a plurality of raised shapes (pin shapes) on the upper surface of the ceiling portion 200c.

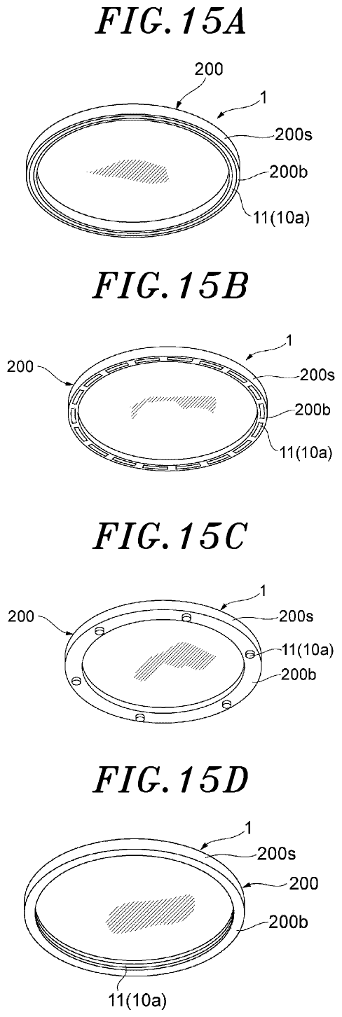

FIG. 15 illustrates examples of disposition of the conductive projections 11 or projections 10a of the component 1 in the lower portion 200b of the second chamber 200. As shown in FIG. 15A, the conductive projections 11 or projections 10a may be disposed in the form of an annular solid-line over the entire circumference of the lower surface of the lower portion 200b; as shown in FIG. 15B, the conductive projections 11 or projections 10a may be disposed in an annular dotted-line shape on the lower surface of the lower portion 200b. As shown in FIG. 15C, the conductive projections 11 or projections 10a may also be disposed as a plurality of raised shapes (pin shapes0 on the lower surface of the lower portion 200b. As shown in FIG. 15D, the conductive projections 11 or projections 10a may be disposed in an annular shape on the inner circumferential surface of the lower portion 200b.

A plasma is generated in the plasma processing space S within the second chamber 200 shown in FIG. 12. The potential generated by the plasma in the plasma processing space S is grounded from the second chamber 200 via, for example, the conductor 380, the lower portion 100f of the first chamber 100, and the sidewall 100s. Also, the potential generated by the plasma is grounded from the second chamber 200 via, for example, the movable part 100m, the bellows 140, the upper portion 100u of the first chamber 100, and the sidewall 100s.

Also, the component 1 may be applied to other members along the conductive path used to ground the potential generated by a plasma in the plasma processing apparatus 50. The component 1 may be applied to the movable part 100m, the bellows 140, or various components of the first chamber 100. The component 1 may be applied to other components constituting the plasma processing apparatus. The component 1 may be applied to the shower head, lower electrode, electrostatic chuck, edge ring, or upper electrode. The shape of the conductive substrate 10, the number, shape, or position of the conductive projections 11 (projections 10a), and the thickness of the coating layer 12 in component 1 may be appropriately modified depending on the specific member of the plasma processing apparatus to which the component 1 is applied.

According to the exemplary embodiment of the present disclosure, the component 1 used in the plasma processing apparatus comprises a conductive substrate 10, a plurality of conductive projections 11, and a coating layer 12, where the coating layer 12 includes a silicon-containing material and is disposed so that the conductive substrate 10 is not exposed and each of the conductive projections 11 is partially exposed. By incorporating the conductive substrate 10 and conductive projections 11 in the component 1, the electrical resistance of the component 1 may be reduced. The partial exposure of the conductive projections 11 allows the conductive projections 11 to serve as electrical contacts. This configuration enables the component 1 to be used for the members along the conductive path for grounding the potential generated by a plasma. Also, the conductive projections 11 may function as a fixing portion for other components. Moreover, by disposing the coating layer 12 made of silicon-containing material on the surface of component 1, the generation of particles from the conductive substrate 10 during plasma generation may be suppressed. By incorporating the conductive substrate 10 and conductive projections 11 in the component 1, mechanical strength of the component 1 may be secured. Also, by forming the coating layer via CVD, adhesion between the coating layer 12 and the conductive substrate 10 or conductive projections 11 may be improved, thereby enhancing the strength of the component 1.

As the conductive substrate 10 is made of carbon, the conductive substrate 10 is made easier to shape, and its electrical resistance may be reduced. When the conductive projections 11 are made of a different metal from that used to form the conductive substrate 10, the exposure of carbon from the conductive substrate 10 may be prevented, thereby suppressing the generation of particles from carbon. By forming the conductive projections 11 or the conductive substrate 10 and the coating layer 12 with materials that have similar thermal expansion characteristics, the strength of component 1 be improved against temperature fluctuations.

When the conductive projections 11 are integrated with the conductive substrate 10, namely, by including the conductive substrate 10 with projections 10a in the component 1, the strength of the component 1 may be enhanced.

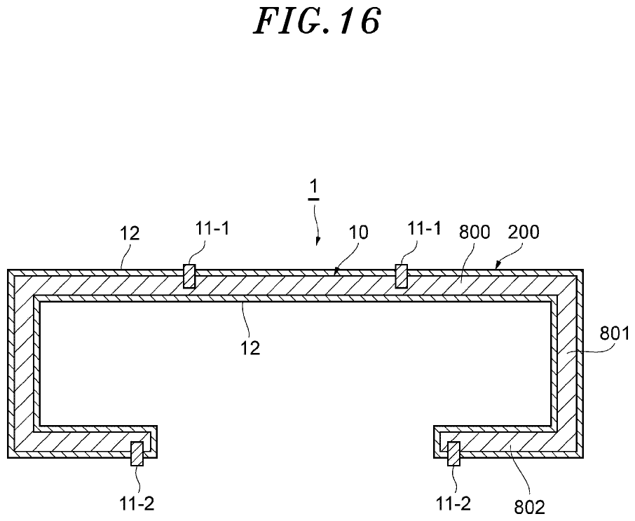

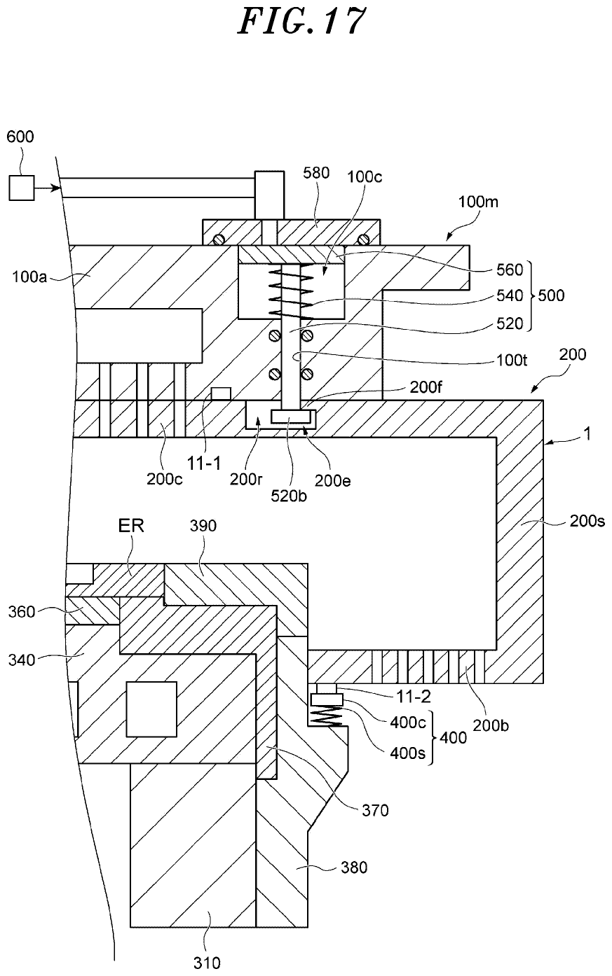

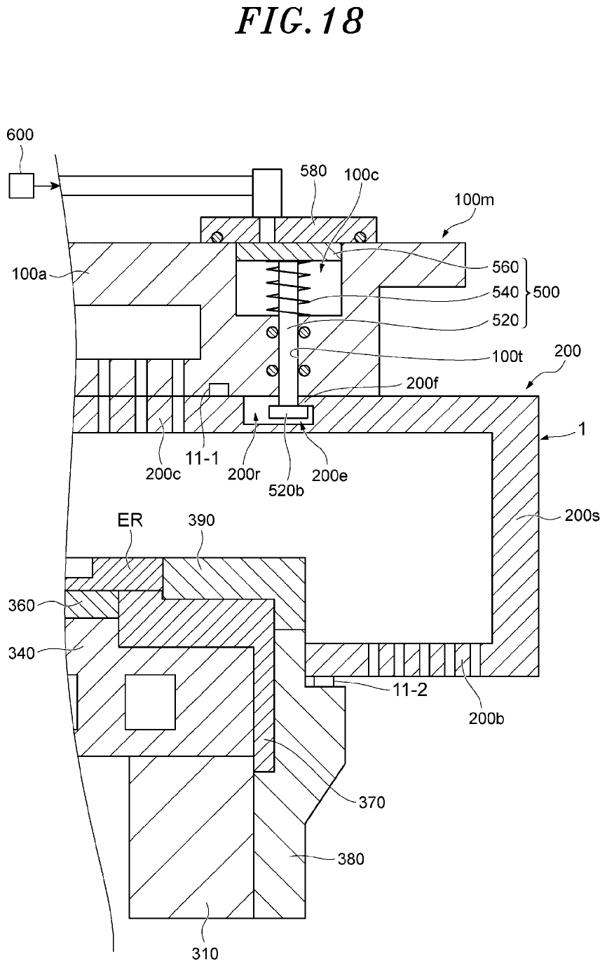

FIG. 16 illustrates a configuration example of the component 1 when the component 1 is applied to the second chamber 200 of the plasma processing apparatus 50. In this case, the component 1 may include a conductive substrate 10, at least one upper conductive projection 11-1, at least one lower conductive projection 11-2, and a coating layer 12 containing silicon.

The conductive substrate 10 may include a ceiling portion 800, an annular side portion 801, and a lower portion 802. The ceiling portion 800 may have an approximately circular plate shape. The annular side portion 801 may have an approximately cylindrical shape. The lower portion 802 may have an approximately circular shape. The lower portion 802 may be extended horizontally toward the inside from the annular side portion 801. Also, a plurality of gas holes may be formed, which penetrate the ceiling portion 800 in the vertical direction. A plurality of exhaust holes may be formed, which penetrate the lower portion 802 in the vertical direction.

One or more upper conductive projections 11-1 may protrude in the upward direction from the upper surface of the ceiling portion 800 of the conductive substrate 10.

One or more lower conductive projections 11-2 may protrude in the downward direction from the lower surface of the lower portion 802 of the conductive substrate 10.

The coating layer 12 may be formed on the surfaces of the conductive chamber substrate 10, the upper conductive projection 11-1, and the lower conductive projection 11-2 so that each of the upper conductive projection 11-1 and lower conductive projection 11-2 has an exposed portion. The coating layer 12 may also be formed on the inner side surface of the gas holes of the ceiling portion 800 or on the inner side surface of the exhaust holes of the lower portion 802.

FIGS. 17 and 18 illustrate an example of configuration of a plasma processing apparatus when the component 1 is applied to the second chamber of the plasma processing apparatus 50.

The exposed portion of the upper conductive projection 11-1 may be in contact with the first member 110a, which is an example of the upper conductive member. The first member 100a may be connected to the ground potential. As shown in FIG. 17, the exposed portion of the lower conductive projection 11-2 may be in contact with the contact 400, which is an example of the lower conductive member. The contact 400 may be connected to the ground potential. As shown in FIG. 18, the exposed portion of the lower conductive projection 11-2 may be in contact with the conductor 380, which is an example of the lower conductive member. The conductor 380 may also be connected to the ground potential. The gas hole in the ceiling portion 800 may interact with the gas hole 100h, and the exhaust hole of the lower portion 802 may interact with the exhaust device 700.

The embodiments of the present disclosure may further include the following aspects.

### Appendix 1

A component for use in a plasma processing apparatus, the component comprising:
a conductive substrate;
a plurality of conductive projections projecting from a surface of the conductive substrate and electrically connected to each other via the conductive substrate; and
an Si-containing coating layer formed on the surface of the conductive substrate and surfaces of the plurality of conductive projections such that each of the plurality of conductive projections is partially exposed.

### Appendix 2

The component of Appendix 1, wherein the conductive substrate is formed of a first material,
the plurality of conductive projections are formed of a second material different form the first material, and
each of the plurality of conductive projections is extended into an inside of the conductive substrate.

### Appendix 3

The component of Appendix 2, wherein the first material includes carbon, and the second material includes metal.

### Appendix 4

The component of Appendix 3, wherein the second material includes tungsten or molybdenum.

### Appendix 5

The component of Appendix 1, wherein the plurality of conductive projections are integrated with the conductive substrate.

### Appendix 6

The component of Appendix 5, wherein the conductive substrate and the plurality of conductive projections are formed of tungsten or molybdenum.

### Appendix 7

The component of any one of Appendixes 1 to 6, wherein the Si-containing coating layer is formed of Si, SiC, Si₃N₄, or SiO₂.

### Appendix 8

The component of any one of Appendixes 1 to 7, wherein at least one of the plurality of conductive projections has an exposed tip and an unexposed side surface.

### Appendix 9

The component of any one of Appendixes 1 to 7, wherein at least one of the plurality of conductive projections has an exposed tip and an exposed side surface.

### Appendix 10

A method for manufacturing a component for use in a plasma processing apparatus, the method comprising:
providing a conductive substrate formed of a first material;
disposing a plurality of conductive projections on a surface of the conductive substrate, wherein the plurality of conductive projections are formed of a second material different from the first material and electrically connected to each other via the conductive substrate; and
forming an Si-containing coating layer on the surface of the conductive substrate and surfaces of the plurality of conductive projections by CVD such that each of the plurality of conductive projections is partially exposed.

### Appendix 11

The method of Appendix 10, wherein the first material includes carbon, and the second material includes metal.

### Appendix 12

The method of Appendix 11, wherein the second material includes tungsten or molybdenum.

### Appendix 13

The method of any one of Appendixes 10 to 12, wherein the Si-containing coating layer is formed of Si, SiC, Si₃N₄, or SiO₂.

### Appendix 14

A method for manufacturing a component for use in a plasma processing apparatus, the method comprising:
providing a conductive substrate formed of a first material;
forming an Si-containing coating layer on a surface of the conductive substrate by CVD; and
attaching a plurality of conductive projections on the conductive substrate, wherein the plurality of conductive projections are formed of a second material different from the first material and are electrically connected to each other via the conductive substrate, and each of the plurality of conductive projections is partially exposed from the Si-containing coating layer.

### Appendix 15

The method of Appendix 14, wherein the first material includes carbon, and the second material includes metal.

### Appendix 16

The method of Appendix 15, wherein the second material includes tungsten or molybdenum.

### Appendix 17

The method of any one of Appendixes 14 to 16, wherein the Si-containing coating layer is formed of Si, SiC, Si₃N₄, or SiO₂.

### Appendix 18

A method for manufacturing a component for use in a plasma processing apparatus, the method comprising:
providing a conductive substrate with a plurality of projections, wherein the conductive substrate is formed of tungsten or molybdenum; and
forming an Si-containing coating layer on a surface of the conductive substrate by CVD such that each of the plurality of projections is partially exposed.

### Appendix 19

The method of Appendix 18, wherein the Si-containing coating layer is formed of Si, SiC, Si₃N₄, or SiO₂.

### Appendix 20

A plasma processing apparatus comprising:
an outer chamber;
a substrate support disposed within the outer chamber;
a lower conductive member disposed around the substrate support and connected to an ground potential;
an upper conductive member disposed in an upper part of the substrate support and connected to the ground potential;
an inner chamber disposed within the outer chamber to define a processing space for processing a substrate on the substrate support; and
an RF power source configured to supply an RF signal to the substrate support to generate plasma within the processing space;
wherein the inner chamber includes:
a conductive chamber substrate;
at least one upper conductive projection projecting from an upper surface of the conductive chamber substrate;
at least one lower conductive projection projecting from an lower surface of the conductive chamber substrate and electrically connected to the at least one upper conductive projection through the conductive chamber substrate; and
an Si-containing coating layer formed on surfaces of the conductive chamber substrate, the at least one upper conductive projection, and the at least one lower conductive projection such that each of the at least one upper conductive projection and the at least one lower conductive projection has an exposed portion,
wherein the exposed portion of the at least one upper conductive projection is in contact with the upper conductive member, and
the exposed portion of the at least one lower conductive projection is in contact with the lower conductive member.

The embodiments described above are provided for illustrative purposes and are not intended to limit the scope of the present disclosure. Various modifications may be made without departing from the scope and spirit of the present disclosure. For example, some components of one embodiment may be added to another embodiment. Also, some components of one embodiment may be replaced with corresponding components of another embodiment.

1. A component for use in a plasma processing apparatus, the component comprising:
a conductive substrate;
a plurality of conductive projections projecting from a surface of the conductive substrate and electrically connected to each other via the conductive substrate; and
an Si-containing coating layer formed on the surface of the conductive substrate and surfaces of the plurality of conductive projections such that each of the plurality of conductive projections is partially exposed.

2. The component of claim 1, wherein the conductive substrate is formed of a first material,
the plurality of conductive projections are formed of a second material different form the first material, and
each of the plurality of conductive projections is extended into an inside of the conductive substrate.

3. The component of claim 2, wherein the first material includes carbon, and the second material includes metal.

4. The component of claim 3, wherein the second material includes tungsten or molybdenum.

5. The component of claim 1, wherein the plurality of conductive projections are integrated with the conductive substrate.

6. The component of claim 5, wherein the conductive substrate and the plurality of conductive projections are formed of tungsten or molybdenum.

7. The component of claim 1, wherein the Si-containing coating layer is formed of Si, SiC, Si₃N₄, or SiO₂.

8. The component of claim 1, wherein at least one of the plurality of conductive projections has an exposed tip and an unexposed side surface.

9. The component of claim 1, wherein at least one of the plurality of conductive projections has an exposed tip and an exposed side surface.

10. A method for manufacturing a component for use in a plasma processing apparatus, the method comprising:
providing a conductive substrate formed of a first material;
disposing a plurality of conductive projections on a surface of the conductive substrate, wherein the plurality of conductive projections are formed of a second material different from the first material and electrically connected to each other via the conductive substrate; and
forming an Si-containing coating layer on the surface of the conductive substrate and surfaces of the plurality of conductive projections by CVD such that each of the plurality of conductive projections is partially exposed.

11. The method of claim 10, wherein the first material includes carbon, and the second material includes metal.

12. The method of claim 11, wherein the second material includes tungsten or molybdenum.

13. The method of claim 10, wherein the Si-containing coating layer is formed of Si, SiC, Si₃N₄, or SiO₂.

14. A method for manufacturing a component for use in a plasma processing apparatus, the method comprising:
providing a conductive substrate formed of a first material;
forming an Si-containing coating layer on a surface of the conductive substrate by CVD; and
attaching a plurality of conductive projections on the conductive substrate, wherein the plurality of conductive projections are formed of a second material different from the first material and are electrically connected to each other via the conductive substrate, and each of the plurality of conductive projections is partially exposed from the Si-containing coating layer.

15. The method of claim 14, wherein the first material includes carbon, and the second material includes metal.

16. The method of claim 15, wherein the second material includes tungsten or molybdenum.

17. The method of claim 14, wherein the Si-containing coating layer is formed of Si, SiC, Si₃N₄, or SiO₂.

18. A method for manufacturing a component for use in a plasma processing apparatus, the method comprising:
providing a conductive substrate with a plurality of projections, wherein the conductive substrate is formed of tungsten or molybdenum; and
forming an Si-containing coating layer on a surface of the conductive substrate by CVD such that each of the plurality of projections is partially exposed.

19. The method of claim 18, wherein the Si-containing coating layer is formed of Si, SiC, Si₃N₄, or SiO₂.

20. A plasma processing apparatus comprising:
an outer chamber;
a substrate support disposed within the outer chamber;
a lower conductive member disposed around the substrate support and connected to an ground potential;
an upper conductive member disposed in an upper part of the substrate support and connected to the ground potential;
an inner chamber disposed within the outer chamber to define a processing space for processing a substrate on the substrate support; and
an RF power source configured to supply an RF signal to the substrate support to generate a plasma within the processing space;
wherein the inner chamber includes:
a conductive chamber substrate;
at least one upper conductive projection projecting from an upper surface of the conductive chamber substrate;
at least one lower conductive projection projecting from a lower surface of the conductive chamber substrate and electrically connected to the at least one upper conductive projection through the conductive chamber substrate; and
an Si-containing coating layer formed on surfaces of the conductive chamber substrate, the at least one upper conductive projection, and the at least one lower conductive projection such that each of the at least one upper conductive projection and the at least one lower conductive projection has an exposed portion,
wherein the exposed portion of the at least one upper conductive projection is in contact with the upper conductive member, and
the exposed portion of the at least one lower conductive projection is in contact with the lower conductive member.
